(19) United States
(12) Patent Application Publication
(10) Pub. No.: US 2026/0279717 A1
(43) Pub. Date: Sep. 17, 2026

(54) CHARGED PARTICLE BEAM DEVICE

(71) Applicant: Samsung Electronics Co., Ltd., Suwon-si (KR)

(72) Inventors: Yujin Cho, Suwon-si (KR); Inyong Kang, Suwon-si (KR); Jihoon Na, Suwon-si (KR); Sanguk Park, Suwon-si (KR); Hyonseok Song, Suwon-si (KR); Hongyul Jung, Suwon-si (KR)

(21) Appl. No.: 19/338,796

(22) Filed: Sep. 24, 2025

(30) Foreign Application Priority Data
Mar. 11, 2025 (KR) 10-2025-0031704

(51) Int. Cl. H01J 37/09; H01J 37/244; H01J 37/26

(52) U.S. Cl. CPC H01J 37/09; H01J 37/244; H01J 37/265; H01J 2237/24475; H01J 2237/2448; H01J 2237/2817

(57) ABSTRACT

A charged particle beam device according to some implementations of the present disclosure comprises: a plurality of columns, a plurality of shielding covers, a chamber, and a detector. Each of the plurality of columns is configured to scan an electron beam on a sample. Each of the plurality of shielding covers surrounds a respective one of the plurality of columns. The chamber is coupled to the plurality of columns, and includes a stage that supports the sample and is disposed apart from ends of the plurality of columns. The detector is configured to detect electrons emitted from the sample. Each of the plurality of columns has a polygonal shape in a plan view.

### CROSS-REFERENCE TO RELATED APPLICATION(S)

This application claims priority to and the benefit of Korean Patent Application No. 10-2025-0031704 filed with the Korean Patent Office on Mar. 11, 2025, the entire contents of which are incorporated herein by reference.

### BACKGROUND

The present disclosure relates to a charged particle beam device.

As semiconductor devices continue to become more highly integrated and miniaturized, securing the precision and reliability of masks used in semiconductor manufacturing processes is becoming increasingly important. Masks are used in the exposure process to form microscopic patterns on wafers, and if there are defects in the mask, this may lead to a decline in the performance of semiconductor devices and a decrease in manufacturing yield. Therefore, a technology to precisely inspect the defects of the mask is essential.

Charged particle beam devices may be used to analyze surfaces, such as to detect patterns or defects on a substrate or to examine the electrical properties of a sample. In particular, by using charged particle beams such as electron beams or ion beams, even minute defects that are difficult to detect using optical methods may be detected with high resolution.

### SUMMARY

According to some implementations of the present disclosure, a charged particle beam device may comprise a plurality of columns, each configured to scan an electron beam on a sample, a plurality of shielding covers respectively surrounding the plurality of columns, a chamber coupled to the plurality of columns, the chamber comprising a stage that supports the sample and is disposed apart from ends of the plurality of columns, and a detector configured to detect electrons emitted from the sample, wherein each of the plurality of columns has a polygonal shape in a plan view.

According to other implementations of the present disclosure, a charged particle beam device may comprise a plurality of shielding covers having polygonal shapes in a plan view, a plurality of columns respectively mounted in the shielding covers and configured to scan electron beams on a sample, a chamber coupled to the plurality of columns and including a stage that supports the sample and is disposed apart from ends of the columns and a detector configured to detect electrons emitted from the sample.

According to other implementations of the present disclosure, a charged particle beam device may comprise a plurality of columns having polygonal shapes in a plan view and each configured to scan an electron beam on a sample, a memory and a processor, wherein the memory stores instructions which, when executed by the processor, cause the apparatus to designate a first region of the sample to be inspected, turn on power of at least some of the plurality of columns, scan the first region using the columns having power turned on and generate image data based on signals obtained from the scanned first region.

The memory may store instructions which, when executed by the processor, cause the charged particle beam device to designate a first region of the sample to be inspected, control power supply to at least some of the plurality of columns to be turned on, scan the first region using the columns whose power is turned on, and generate image data based on signals obtained by scanning the first region.

A method of operating a charged particle beam device according to some implementations of the present disclosure may comprise designating a first region of a sample to be inspected, controlling power supply to turn on at least some of a plurality of columns, scanning the first region using the columns whose power is turned on, and generating image data based on signals obtained by scanning the first region.

The method of operating the charged particle beam device may further include outputting the image data of the first region through a display.

The method may further include outputting the respective image data obtained by scanning using the respective columns whose power is turned on.

The method may further include turning on the power of all of the plurality of columns.

The method may further include designating a second region as a partial region of the first region and turning on the power of columns corresponding to the second region among the plurality of columns.

In the method of operating the charged particle beam device, the charged particle beam device may comprise a plurality of columns each having a polygonal shape in a plan view.

In the method, the plurality of columns may be arranged in a honeycomb pattern in a plan view.

The charged particle beam device may further include a plurality of shielding covers respectively surrounding the plurality of columns.

The plurality of shielding covers may comprise a material having a shielding effect, such as a permalloy.

The plurality of shielding covers may have a hexagonal shape in a plan view.

The plurality of shielding covers may be arranged in a honeycomb pattern in a plan view.

The implementations are intended to provide a charged particle beam device having a plurality of electron beam columns, thereby improving the performance and convenience of maintenance of the device by optimizing the arrangement method and shape of the electron beam columns.

### BRIEF DESCRIPTION OF THE DRAWINGS

FIG. 1 is a schematic drawing of a charged particle beam device according to some implementations.

FIG. 2 is a block diagram of a control unit included in the charged particle beam device according to some implementations.

FIG. 3 is a cross-sectional view of one electron beam column included in a charged particle beam device according to some implementations.

FIG. 4 is a perspective view of one electron beam column included in a charged particle beam device according to some implementations.

FIG. 5 is a plan view of one electron beam column included in a charged particle beam device according to some implementations.

FIG. 6 is a plan view of one electron beam column included in a charged particle beam device according to some implementations.

FIG. 7 is a drawing showing a plurality of column assemblies included in a charged particle beam device according to some implementations.

FIG. 8 is a drawing showing a plurality of column assemblies included in a charged particle beam device according to some implementations.

FIG. 9 is a drawing for explaining scanning the inspection area of a sample in a conventional charged particle beam device.

FIG. 10 is a diagram illustrating scanning of an inspection area of a sample in a charged particle beam device according to some implementations.

FIG. 11 is a flowchart illustrating an operation method of a charged particle beam device according to some implementations.

FIG. 12 is a flowchart illustrating an operation method of a charged particle beam device according to some implementations.

FIG. 13 is a diagram illustrating an example of a computer device implementing a charged particle beam device according to some implementations.

### DETAILED DESCRIPTION

Hereinafter, various implementations of the present disclosure will be described in detail with reference to the attached drawings so that a person having ordinary skill in the art to which the present disclosure pertains may easily implement the invention. The present disclosure may be embodied in many different forms and is not limited to the implementations described herein.

In order to clearly explain the present disclosure, parts irrelevant to the description are omitted, and the same reference numerals are used for identical or similar components throughout the specification.

In addition, the size and thickness of each component shown in the drawing are arbitrarily shown for convenience of explanation, so the present disclosure is not necessarily limited to what is shown. To clearly represent the various layers and areas in the drawing, the thickness is enlarged and shown. And in the drawing, for convenience of explanation, the thickness of some layers and areas is exaggerated.

Also, when we say that a part, such as a layer, membrane, region, or plate, is “over” or “on” another part, this comprises not only cases where it is “directly over” the other part, but also cases where there are other parts in between. Conversely, when we say that a part is “directly above” another part, we mean that there is no other part in between. Also, being “above” or “on” a reference part means being located above or below the reference part, and does not necessarily mean being located “above” or “on” the opposite direction of gravity.

Additionally, throughout the specification, whenever a part is said to “include” a component, this does not mean that it excludes other components, but rather that it may comprise other components, unless otherwise specifically stated.

Additionally, throughout the specification, when we say “in plan”, we mean when the target portion is viewed from above, and when we say “in cross section”, we mean when the target portion is viewed from the side in a cross-section cut vertically.

Additionally, terms such as “ . . . part”, “ . . . device”, “ . . . module”, etc. described in the specification perform at least one function or operation, and may be implemented by hardware or software, or by a combination of hardware and software. Additionally, a plurality of “ . . . modules”, a plurality of “ . . . units”, or a plurality of “ . . . modules” may be integrated into at least one module and implemented with at least one processor, except for a “ . . . unit”, a “ . . . unit”, or a “ . . . module” that needs to be implemented with specific hardware.

In this specification, “transmitting,” “transmitting,” “providing,” or “receiving” may comprise not only directly transmitting, transmitting, providing, or receiving, but also indirectly transmitting, transmitting, providing, or receiving via another device or by using a bypass route.

In this specification, expressions described in the singular may be interpreted as singular or plural, unless explicit expressions such as “one” or “singular” are used.

Charged particle beam devices are designed with a structure that comprises the plurality of electron beam columns to shorten the inspection time. Utilizing the plurality of electron beams may significantly improve inspection speed compared to single beam methods, but the stability of the system may be reduced due to interference between the plurality of beams and heat generation in the column.

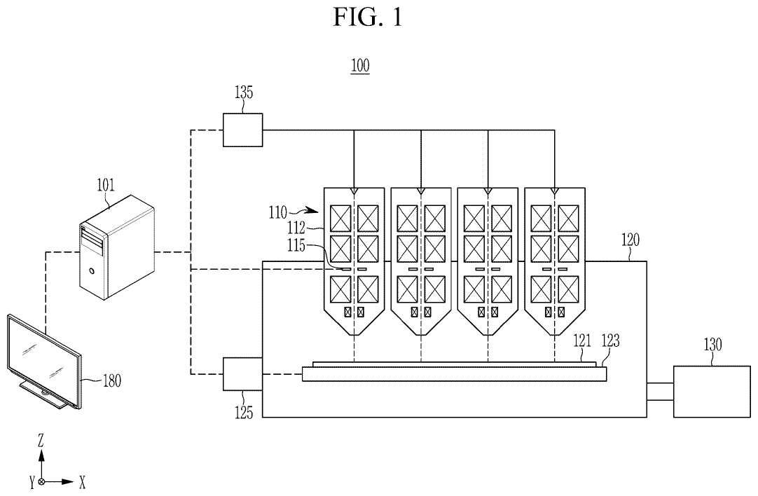

FIG. 1 is a schematic drawing of a charged particle beam device according to some implementations.

Referring to FIG. 1, a charged particle beam device 100 may be provided. According to some implementations, a charged particle beam device 100 may comprise a plurality of columns 110, a chamber 120, a stage 123 for supporting a sample 121 within the chamber 120, a stage driving device 125, a vacuum pump 130 connected to the chamber 120, a detector 115 for detecting electrons emitted from the sample 121, a column control unit 135, a control unit 101, and a display 180. According to some implementations, the charged particle beam device 100 may comprise a shielding cover 112 surrounding each of a plurality of columns 110. In some implementations, the charged particle beam device 100 may omit at least one of the components described above or may additionally include other components (e.g., a sample transport module).

In the present disclosure, the x direction and the y direction may be directions intersecting each other. For example, the x and y directions may be orthogonal to each other. In the present disclosure, the x direction may be the movement direction of the stage 123 supporting the sample 121. The y direction may be the direction in which the electron beam is scanned along the surface of the sample 121. The z direction is a direction perpendicular to the x and y directions, and may be the direction in which the electron beam is incident on the sample 121.

According to some implementations, the chamber 120 may provide an inspection space for inspecting a sample 121. The inspection space may be maintained in a vacuum. The inspection space may be maintained in a vacuum state by a vacuum pump 130. In other words, the inside of the chamber 120 may be maintained in a vacuum state by a vacuum pump 130.

According to some implementations, a sample 121 may be placed within a chamber 120. More specifically, a sample 121 may be placed on a stage 123 within a chamber 120. In this specification, the sample 121 may be understood as a concept including a photomask, a reticle, a wafer, etc. However, it is not limited thereto, and the sample 121 may comprise various objects or elements that are the subject of examination or analysis.

According to some implementations, the charged particle beam device 100 may comprise a plurality of columns 110. For example, the charged particle beam device 100 may comprise a plurality of columns 110 to improve the speed of inspection or analysis. In this specification, the column may be referred to as an electron beam column.

In some implementations, at least a portion of each of the plurality of columns 110 may be positioned within the chamber 120. Each of the plurality of columns 110 may irradiate an electron beam toward a sample 121 on the stage 123. The column 110 may irradiate an electron beam to the sample 121 to charge a specific area of the sample 121, for example, a metal pattern (electrode), a chrome layer, or an insulating substrate. In general, when the yield of emitted electrons (Secondary Electrons, SE) is greater than 1, the corresponding area of the irradiated sample 121 may be charged with a positive charge. Alternatively, if the emission electron yield is less than 1, the corresponding region of the investigated sample 121 may be charged with a negative charge.

In some implementations, the column 110 may irradiate a scanning electron beam toward a sample 121 on the stage 123, and a specific area of the charged sample 121 may be scanned again by the scanning electron beam. Through this, the charged particle beam device 100 may precisely determine a specific defect in the sample 121 by analyzing the local potential change and the difference in the emission electron yield according to charge accumulation.

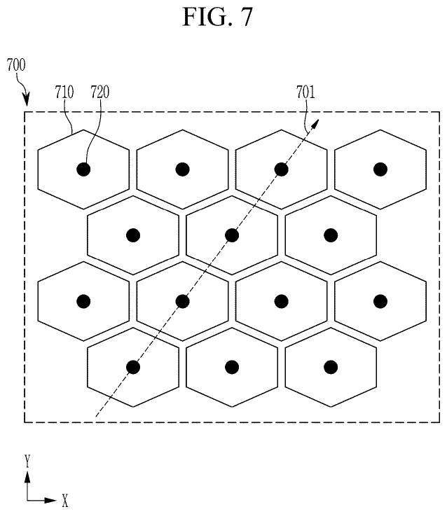

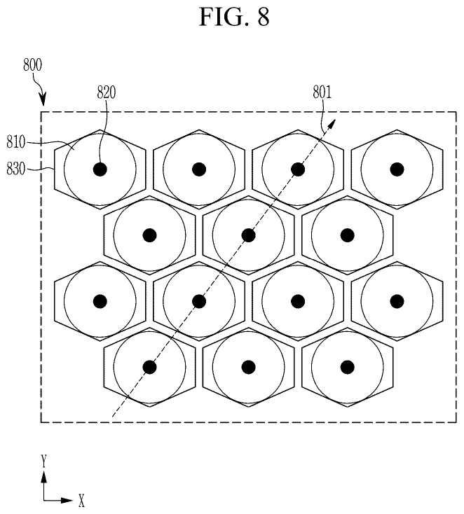

According to some implementations, a plurality of columns 110 may be arranged spaced apart at regular intervals along one direction. Here, one direction may mean a direction that forms a predetermined angle with the x-direction and the y-direction. Specific details related to the arrangement of the plurality of columns 110 are described below with reference to FIGS. 7 and 8.

Meanwhile, in FIG. 1, four columns 110 are depicted as being arranged, but this disclosure is not limited thereto. In other words, the number of the plurality of columns 110 may be varied. At this time, each of the plurality of columns 110 may generate an electron beam and scan it toward the sample 121.

In some implementations, a shielding cover 112 may surround each of the plurality of columns 110. In some implementations, the shielding cover 112 may comprise an alloy having a high magnetic permeability or a material capable of magnetic shielding. For example, the shielding cover 112 may comprise permalloy. For example, the shielding cover 112 may be composed of, but is not limited to, permalloy.

Here, permalloy generally refers to a high-permeability alloy containing nickel Ni and iron Fe and may mean an ultra-high permeability material with high permeability, wear resistance, ductility, and malleability. However, it is not limited thereto, and the shielding cover 112 may comprise various materials having electromagnetic shielding performance.

According to some implementations, the stage 123 may be located within the chamber 120. In some implementations, the stage 123 may be positioned below the columns 110. Specifically, the stage 123 may be positioned so as to be spaced apart from the ends of the columns 110 to support the sample 121. The sample 121 may be placed on the upper surface of the stage 123.

According to some implementations, the stage 123 may comprise a chuck or the like for fixing the sample 121. For example, the stage 123 may comprise an electrostatic chuck ESC that holds the sample 121 with electrostatic force or a vacuum chuck that holds the sample 121 with vacuum pressure.

In some implementations, the stage 123 may move horizontally (e.g., in the x-direction) relative to the column 110. Accordingly, the sample 121 on the stage 123 may also move in a horizontal direction (e.g., x direction) with respect to the column 110.

According to some implementations, the stage drive device 125 may move the stage 123. For example, the stage driving device 125 may move the stage 123 on which the sample 121 is placed in a horizontal direction (e.g., x direction).

According to some implementations, the column control unit 135 may control a plurality of columns 110. Specifically, the column control unit 135 may control each or all of the plurality of columns 110.

According to some implementations, the column control unit 135 may control power to each of the plurality of columns 110. For example, the column control unit 135 may control the power of at least some of the plurality of columns 110 to be turned on and the power of other some to be turned off as needed. Additionally, for example, the column control unit 135 may control the power of all of the plurality of columns 110 to be on or off.

For example, the column control unit 135 may control the angle of the electron beam scanned by the column 110, the secondary electron yield, and/or the irradiation time. Additionally, the column control unit 135 may control the path of the electron beam injected by the column 110.

According to some implementations, the detector 115 may detect emitted electrons and/or backscatter electrons emitted from the sample 121 by the electron beam. Hereinafter, in this specification, the emitted electrons may be referred to as secondary electrons.

In some implementations, the detector 115 may be installed within the columns 110. However, it is not limited thereto, and the detector 115 may also be installed inside the chamber 120. Since the amount of secondary electrons and backscattered electrons emitted may vary depending on the type of the sample 121 to be inspected and the intensity and angle of the electron beam injected into the sample 121, the detector 115 may detect either one of the secondary electrons and backscattered electrons or both simultaneously.

In some implementations, the detector 115 may transmit information about secondary electrons and/or backscattered electrons to the control unit 101.

According to some implementations, the control unit 101 may control the column control unit 135, the detector 115 and/or the stage driving device 125. For example, the control unit 101 may control each component such that the column control unit 135, the detector 115, and/or the stage driving device 125 perform the operations described above.

According to some implementations, the control unit 101 may obtain information about secondary electrons from the detector 115. According to some implementations, the control unit 101 may generate image and/or numeric data based on secondary electron information obtained from the detector 115. For example, the control unit 101 may generate a VC image (Voltage Contrast Image) based on the acquired secondary electronic information. Alternatively, the control unit 101 may quantitatively analyze the amount of secondary electrons detected from the detector 115 to generate numerical data. In other words, the control unit 101 may process the secondary electron signal received by the detector 115 to generate not only an SEM image but also numerical data on the amount of secondary electrons.

Here, the SEM image may be, but is not limited to, a grayscale image. Here, a grayscale image means an image expressed in grayscale. For example, a pixel may have an integer value between 0 and 255. Here, 0 corresponds to black and 255 corresponds to white. In this example, if the total of 256 integer values that a pixel may have are expressed in 256 levels of brightness, it becomes an 8-bit grayscale image, and if the total of 256 integer values that a pixel may have are expressed in 8 levels of brightness, it becomes a 3-bit grayscale image. The higher the gray level, the brighter the SEM image may be.

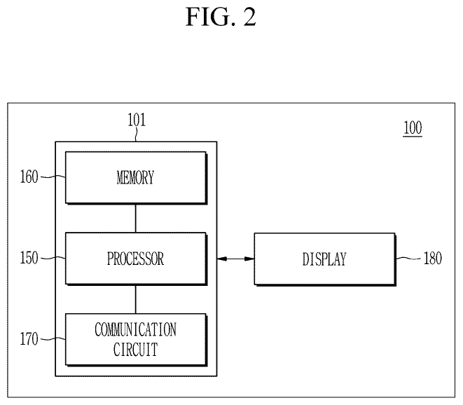

According to some implementations, the display 180 may be operatively connected to the control unit 101. The display 180 may visually provide data generated by the control unit 101 to the user. Specifically, the display 180 may visually provide the user with various data related to defects in the sample 121. For example, the display 180 may output image data generated by the control unit 101. For more detailed information, please refer to FIG. 2 below.

In addition, the charged particle beam device 100 according to some implementations may further include a sample transport module. In some implementations, a sample transport module may transport a sample 121 into the chamber 120. By transporting the sample 121 into the chamber 120 using a sample transport module, contamination of the sample 121 may be prevented and the accuracy of alignment of the sample 121 may be improved.

FIG. 2 is a block diagram of a control unit included in the charged particle beam device according to some implementations.

Referring to FIG. 2, a charged particle beam device 100 according to some implementations may comprise a control unit 101 and a display 180 connected to the control unit 101.

According to some implementations, the control unit 101 may comprise at least one processor 150, memory 160, and a communication circuit 170. According to some implementations, the charged particle beam device 100 may further include a display 180. In some implementations, the charged particle beam device 100 may omit at least one of the components described above or may additionally include other components.

According to some implementations, the processor 150 may control the overall operation of the charged particle beam device 100. The processor 150 may comprise an accelerator, which is a dedicated circuit for data operations. An accelerator may be a functional block that specializes in performing a specific function of the processor 150. An accelerator may comprise a GPU (Graphics Processing Unit), an NPU (Neural Processing Unit), or a DPU (Data Processing Unit). A GPU may be a block that specializes in processing graphic data. An NPU may be a block specialized for performing AI calculations and inference. A DPU may be a block that specializes in data transmission.

According to some implementations, the processor 150 may execute instructions stored in memory 160. The processor 150 may execute applications stored in memory 160. Each application may be a collection of instructions. The processor 150 may cause the charged particle beam device 100 to perform the operations described below by executing instructions stored in the memory 160. The operations described below as being performed by the processor 150 may be performed by the processor 150 and/or at least one other component of the charged particle beam device 100 connected to the processor 150, and thus may be understood to be performed by the charged particle beam device 100.

According to some implementations, the memory 160 may store data used or received by at least one component of the charged particle beam device 100 (e.g., processor 150, communication circuit 170, display 180). Memory 160 may store instructions executed by at least one processor 150.

According to some implementations, the memory 160 may store instructions for executing a method of analyzing (or inspecting) a defect in a sample (e.g., sample 121 of FIG. 1). For example, the memory 160 may store commands for executing a method of correcting an image of a surface of a sample 121. Additionally, for example, the memory 160 may store commands for executing a method of analyzing an image of the surface of a sample 121. The commands may be stored in memory 160 as code of a computer program.

According to some implementations, the memory 160 may store one or more artificial intelligence (or neural network) models and a data set used to train the models. For example, the learning algorithms used by artificial intelligence models may comprise various algorithms such as supervised, unsupervised, semi-supervised, and reinforcement learning. Additionally, the artificial intelligence model may comprise the plurality of artificial neural network layers, for example, a deep neural network, a CNN, an RNN, an RBM, a DBN, a BRDNN, a deep Q-network, or a combination thereof, but is not limited to the examples described above.

According to some implementations, the memory 160 may store data transmitted and received through the communication circuit 170. For example, the memory 160 may store information about secondary electrons received from a detection unit (e.g., detector 115 of FIG. 1) through a communication circuit 170.

According to some implementations, the memory 160 may store data generated by the processor 150. For example, the memory 160 may store numerical data on the amount of SEM images and/or secondary electrons generated by the processor 150.

In some implementations, the memory 160 may be implemented as a non-volatile memory, such as a Read-Only Memory ROM, a Magnetic RAM MRAM, a SpinTransfer Torque MRAM (SpinTransfer Torque MRAM), a Conductive bridging RAM CBRAM, a Ferroelectric RAM FeRAM, a Phase RAM PRAM, a Resistive RAM, etc. However, it is not limited to this.

In other implementations, the memory 160 may be implemented as a volatile memory, such as a dynamic random-access memory DRAM, a synchronous DRAM SDRAM, a double data rate SDRAM DDR SDRAM, a low power double data rate SDRAM LPDDR SDRAM, a graphics double data rate SDRAM GDDR SDRAM, a DDR2 SDRAM, a DDR3 SDRAM, a DDR4 SDRAM, a DDR5 SDRAM, and the like. However, it is not limited to this.

According to some implementations, the communication circuit 170 may support establishment of a wired or wireless communication channel between the control unit 101 and an external electronic device, and performance of communication through the established communication channel. For example, the processor 150 may obtain data related to secondary electrons emitted from a sample 121 through a communication circuit 170. Specifically, the control unit 101 may obtain data related to the secondary electrons from the detector 115 through the communication circuit 170.

According to some implementations, the communication circuit 170 may comprise a wireless communication module (e.g., a cellular communication module, a short-range wireless communication module, or a global navigation satellite system (GNSS) communication module) or a wired communication module (e.g., a local area network (LAN) communication module, or a power line communication module).

According to some implementations, the processor 150 may communicate with an external electronic device via a first network (e.g., a short-range communication network such as Bluetooth, WiFi direct, or infrared data association (IrDA)) or a second network (e.g., a long-range communication network such as a cellular network, the Internet, or a computer network (e.g., a LAN or WAN)) using the communication circuit 170. The various types of communication circuits 170 described above may be implemented in one chip or in separate chips.

According to some implementations, the display 180 may display information processed on the display 180 under the control of the processor 150. For example, the display 180 may display various contents (e.g., text, images, videos, icons, and/or symbols). According to some implementations, the display 180 may comprise a liquid crystal display LCD, a light emitting diode LED display, or an organic light emitting diode OLED display.

According to some implementations, the display 180 may comprise, for example, a touch screen and may receive touch, gesture, proximity, or hovering input using an electronic pen or a part of the user's body. In this case, the display 180 may also be used as an input device but is not limited thereto. In some implementations, the charged particle beam device 100 may comprise a separate input device.

According to some implementations, the display 180 may visually provide various information to a user of the charged particle beam device 100. In some implementations, the display 180 may display image data acquired by having columns 110 scan the surface of the sample 121.

According to some implementations, the display 180 may output each image data scanned using a plurality of columns 110 together. In other words, the display 180 may simultaneously output the plurality of image data scanned using the plurality of columns 110. However, it is not limited to this, and the display 180 may separately output each scanned image data using the plurality of columns 110.

According to some implementations, the display 180 may display data processed by the processor 150. According to some implementations, the display 180 may display a GUI (graphic user interface) indicating the result of determining whether the sample 121 is defective after the defect of the sample 121 is analyzed by the processor 150.

In some implementations, the display 180 may display a surface image of a sample 121 together with data related to a defect in the sample 121. For example, the display 180 may display a surface image of a sample 121 and data related to a defect in the sample 121 by overlapping them, but is not limited thereto, and the display form may be changed according to various implementations.

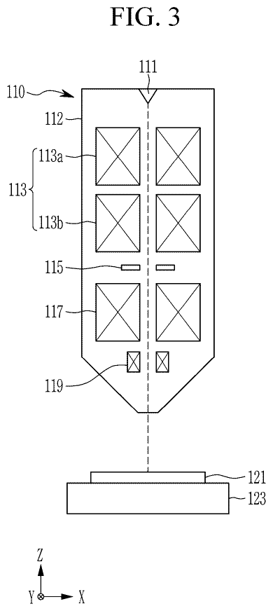

FIG. 3 is a cross-sectional view of one electron beam column included in a charged particle beam device according to some implementations.

Referring to FIG. 3, the column 110 may comprise an electron gun 111, a shielding cover 112, a condenser lens 113, a detector 115, an objective lens 117, and a deflector 119.

In some implementations, the shielding cover 112 may surround the column 110. As illustrated in FIG. 1, each of the plurality of shielding covers 112 may surround each of the plurality of columns 110. In other words, the shielding cover 112 may be independently positioned for the plurality of columns 110. That is, a shielding cover 112 may be individually applied to each column 110, thereby minimizing interference between each column 110.

In some implementations, the shielding cover 112 may provide a beam generating space. The shielding cover 112 may protect the electron gun 111, the condenser lens 113, and the objective lens 117 from external interference.

According to some implementations, the shielding cover 112 may perform an electromagnetic shielding function. The shielding cover 112 may reflect or absorb electromagnetic waves to prevent the electron beam inside the column 110 from being affected by external interference. In addition, the shielding cover 112 may prevent static electricity that may be introduced from the outside, thereby enabling stable operation of the column 110.

As described above, the shielding cover 112 according to the present disclosure provides an independent shielding function for each column 110 in a multi-column structure, thereby minimizing electron beam interference and supporting precise analysis.

In addition, as described above, the shielding cover 112 according to the present disclosure may improve the convenience of maintenance by independently separating each column 110 in a multi-column structure.

In some implementations, the electron gun 111 may be positioned within a beam generating space provided by a shielding cover 112. The electron gun 111 may irradiate an electron beam onto a sample 121. The sample 121 may be positioned on the stage 123. For example, the sample 121 may comprise, but is not limited to, a photomask, a reticle, or a wafer.

In some implementations, the electron gun 111 may generate and accelerate electrons. The electron gun 111 may comprise a filament made of a metal such as tungsten. When the electron gun 111 heats the filament to a high temperature, electrons bound to atoms on the surface of the filament may be emitted into the vacuum.

According to some implementations, an electron beam emitted from an electron gun 111 may pass through a condenser lens 113 and a deflector 119 and travel outside a shielding cover 112. Additionally, the electron gun 111 may comprise an accelerating electrode, which may accelerate electrons emitted from the filament using a high voltage. The accelerated electron beam then passes through a condenser lens 113 and an objective lens 117 and may be precisely irradiated onto a sample 121.

In some implementations, a condenser lens 113 may be positioned below the electron gun 111. A condenser lens 113 may focus an electron beam emitted from an electron gun 111 into a narrow area. The condenser lens 113 may comprise a cylindrical shape, but is not limited thereto. The condenser lens 113 may comprise an electromagnet and/or a capacitor. A condenser lens 113 may control the direction of travel of an electron beam by using the Lorentz force applied to an electron beam moving in a magnetic field.

According to some implementations, the condenser lens 113 may comprise a first condenser lens 113a that primarily focuses the generated and accelerated electron beam and a second condenser lens 113b that secondarily focuses the electron beam focused from the first condenser lens 113a. Here, the diameter of the electron beam focused by the second condenser lens 113b may be smaller than the diameter of the electron beam focused by the first condenser lens 113a. Through this, the diameter of the focused electron beam may be reduced to the level of tens of nanometers.

According to some implementations, the detector 115 may detect a secondary electron beam emitted in response to a pattern of the sample 121 when an electron beam is irradiated to the sample 121 and may output a detection signal. According to some implementations, a detection signal acquired by the detector 115 may be transmitted to a control unit (e.g., control unit 101 of FIGS. 1 and 2).

According to some implementations, the objective lens 117 may focus an electron beam focused through the condenser lens 113 onto a sample 121. For example, the objective lens 117 may determine the size of the electron beam irradiated to the sample 121 and may be positioned close to the surface of the sample 121 to have a short focal length to create an electron beam with a small diameter. That is, the shorter the distance between the objective lens 117 and the surface of the sample 121, the smaller the spot of the electron beam may be formed. In this way, the objective lens 117 may adjust the resolution of the sample image by adjusting the diameter of the electron beam.

According to some implementations, the deflector 119 may adjust the scanning angle and scanning direction of the electron beam so that the electron beam may be scanned by scanning the surface of the sample 121. For example, when current is applied to the deflector 119, the electron beam moves in the y direction and may be scanned on the surface of the sample 121. Specifically, the degree to which the electron beam is bent may be controlled depending on the size of the current applied to the deflector 119, and the direction in which the electron beam is bent may be controlled depending on the direction of the applied current. Therefore, the scanning angle and scanning direction of the electron beam may be controlled by controlling the size and direction of the current applied to the deflector 119. The deflector 119 may comprise, for example, an electromagnet and/or a capacitor. However, it is not limited thereto, and the deflector 119 may comprise other structures capable of changing the path of the electron beam.

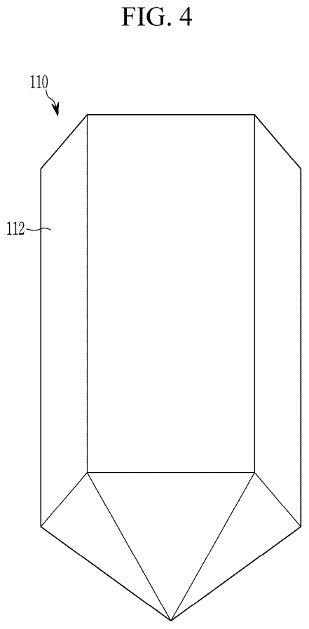

FIG. 4 is a perspective view of one electron beam column included in a charged particle beam device according to some implementations.

Referring to FIG. 4, a charged particle beam device (e.g., the charged particle beam device 100 of FIG. 1) may comprise a plurality of columns 110, and each of the columns 110 may have a hexagonal pillar shape. For example, if the housing of a plurality of columns 110 is a shielding cover 112, each column 110 may have a hexagonal column shape. Or, for example, if the shielding cover 112 is separated from the housing of the columns 110 and surrounds the columns 110, the shielding cover 112 may have a hexagonal column shape.

For convenience of explanation, each column 110 in FIG. 4 is described as having a hexagonal prism shape.

According to some implementations, a hexagonal column 110 may provide optimal layout efficiency while maximizing space utilization in a multi-column system in which the plurality of columns 110 are integrated, and at the same time, may improve structural stability. This is because hexagons have the geometric characteristic of being able to be arranged at a higher density than circles or squares per unit area.

Specifically, since each of the plurality of columns 110 has a hexagonal column shape, the spacing between the electron beams scanned by the columns 110 may be maintained larger than when the columns have circular or square column shapes of the same cross-sectional area because fewer hexagonal columns than square or circular columns are able to scan a same sample area. Accordingly, the phenomenon of cross talk between columns 110 is reduced while the electron beam scans the sample surface, and signal distortion may be minimized, enabling more precise inspection and analysis.

In addition, the symmetrical structure of the hexagonal prism shape may increase the physical stability of the multi-column system and minimize structural deformation due to external environments (e.g., temperature changes or vibrations). This could be an important factor in improving the reliability of charged particle beam devices performing high-resolution imaging and precise patterning.

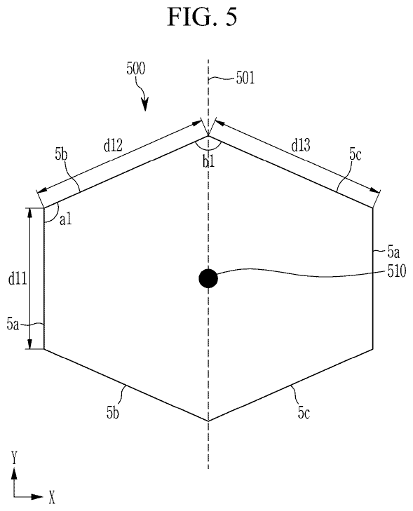

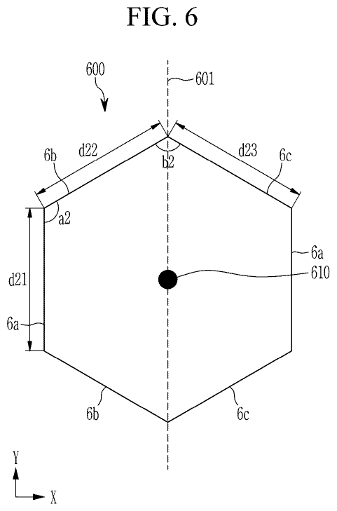

Below, with reference to FIGS. 5 and 6, the planar shape of each column 110 will be described in more detail.

In addition, as described below, the plurality of columns 110 according to the present disclosure each have a hexagonal column shape and may be arranged in a honeycomb structure. The honeycomb structure may provide the advantage of securing maximum integration with minimum space waste while effectively reducing interference between columns 110 by utilizing the geometric characteristics of the hexagon. Specific details related to this are described later with reference to FIGS. 7 and 8.

FIG. 5 is a plan view of one electron beam column included in a charged particle beam device according to some implementations.

Referring to FIG. 5, each of a plurality of columns 110 (e.g., the column 110 of FIG. 1) included in a charged particle beam device (e.g., the charged particle beam device 100 of FIG. 1) according to some implementations may have a first hexagonal shape 500 on a plane. Or, for example, when a shielding cover (e.g., a shielding cover 112 of FIG. 1) is separated from the housing of the columns 110 and surrounds the columns 110, the shielding cover 112 may have a first hexagonal shape 500 in a plane.

For convenience of explanation, each column 110 in FIG. 5 is described as having a hexagonal prism shape.

According to some implementations, the first hexagonal shape 500 may comprise six sides. Specifically, the first hexagonal shape 500 may be composed of first sides 5a facing each other, and second sides 5b and third sides 5c connecting the first sides 5a.

In the first hexagonal shape 500, a first virtual line 501 that is positioned parallel to the first side 5a and passes through the center 510 of the column 110 may be set, and the second side 5b and the third side 5c may be symmetrical with respect to the first virtual line 501. That is, the first hexagonal shape 500 may form a symmetrical structure based on the first virtual line 501. Here, the center 510 of the column 110 corresponds to the position through which the electron beam passes.

According to some implementations, the first side 5a may have a first length d11, the second side 5b may have a second length d12, and the third side 5c may have a third length d13. In some implementations, the second length d12 may be different from the first length d11 and may be equal to the third length d13. In other words, the first length d11 may be different from the second length d12 and the third length d13, and the second length d12 and the third length d13 may be equal to each other.

According to some implementations, the first angle a1 between the first side 5a and the second side 5b may be different from the second angle b1 between the second side 5b and the third side 5c.

Since the plurality of columns 110 according to the implementations of the present disclosure have the first hexagonal shape 500 described above on a plane, the arrangement between the columns 110 may be optimized. In addition, integration may be maximized and inter-beam interference may be minimized in a multi-column system.

FIG. 6 is a plan view of one electron beam column included in a charged particle beam device according to some implementations.

Referring to FIG. 6, each of a plurality of columns 110 (e.g., the column 110 of FIG. 1) included in a charged particle beam device (e.g., the charged particle beam device 100 of FIG. 1) according to some implementations may have a second hexagonal shape 600 on a plane. Or, for example, when a shielding cover (e.g., a shielding cover 112 of FIG. 1) is separated from the housing of the columns 110 and surrounds the columns 110, the shielding cover 112 may have a second hexagonal shape 600 in a plane.

For convenience of explanation, each column 110 in FIG. 6 is described as having a hexagonal prism shape.

In some implementations, the second hexagonal shape 600 may comprise six sides. The second hexagonal shape 600 may be a regular hexagon. Specifically, the second hexagonal shape 600 may be composed of fourth sides 6a facing each other, and fifth sides 6b and sixth sides 6c connecting the fourth sides 6a.

In the second hexagonal shape 600, a second virtual line 601 that is positioned parallel to the fourth side 6a and passes through the center 610 of the column 110 may be set, and the fifth side 6b and the sixth side 6c may be symmetrical with respect to the second virtual line 601. That is, the second hexagonal shape 600 may form a symmetrical structure based on the second virtual line 601. Here, the center 610 of the column 110 corresponds to the position where the electron beam passes.

According to some implementations, the fourth side 6a may have a fourth length d21, the fifth side 6b may have a fifth length d22, and the sixth side 6c may have a sixth length d23. In some implementations, the fourth length d21, the fifth length d22 and the sixth length d23 may all be equal to each other. In some implementations, the third angle a2 between the fourth side 6a and the fifth side 6b may be equal to the fourth angle b2 between the fifth side 6b and the sixth side 6c.

Since the plurality of columns 110 according to the implementations of the present disclosure have the second hexagonal shape 600 described above on a plane, the arrangement between the columns 110 may be optimized. In addition, integration may be maximized and inter-beam interference may be minimized in a multi-column system.

FIG. 7 is a drawing showing a plurality of column assemblies included in a charged particle beam device according to some implementations.

Referring to FIG. 7, a charged particle beam device (e.g., the charged particle beam device 100 of FIG. 1) according to some implementations of the present disclosure may comprise a first assembly 700 composed of a plurality of columns 710. Here, the first assembly 700 may mean a structure in which a plurality of columns 710 are integrated along a specific arrangement pattern.

According to some implementations, the first assembly 700 may be composed of columns 710 arranged in a honeycomb shape. The honeycomb-shaped arrangement provides a geometrically optimized structure that may place the maximum number of columns within the same area, and may have the effect of minimizing cross talk between columns 710 and improving beam quality.

Additionally, the centers 720 of the columns 710 may be arranged at regular intervals along a first direction 701. In other words, the columns 710 may be arranged at regular intervals along the first direction 701. Accordingly, when the charged particle beam device 100 operates, a uniform beam spacing may be maintained during the scanning and irradiation process of the electron beam.

In some implementations, the first direction 701 may form an acute angle with the x-direction. Additionally, the first direction 701 may form an acute angle with the y direction. Here, the x direction may be the movement direction of a stage (e.g., stage 123 in FIG. 1) supporting a sample (e.g., sample 121 in FIG. 1). The y direction may be the direction in which the electron beam is scanned along the surface of the sample 121 (scanning direction).

According to some implementations, the columns 710 are not simply arranged in series along the x-direction or the y-direction but are arranged along a first direction 701 that forms an acute angle with the x-direction and the y-direction, thereby forming an optimized arrangement structure.

Specifically, the first assembly 700 according to the present disclosure has a honeycomb structure and an aligned arrangement in the first direction 701, thereby allowing as many columns 710 as possible to be arranged within the same area while securing the maximum spacing between beams scanned by individual columns.

FIG. 8 is a drawing showing a plurality of column assemblies included in a charged particle beam device according to some implementations.

Referring to FIG. 8, when a shielding cover 830 (e.g., a shielding cover 112 of FIG. 1) is separated from the housing of the columns 810 (e.g., a column 110 of FIG. 1) and surrounds the columns 810, the charged particle beam device (e.g., a charged particle beam device 100 of FIG. 1) may comprise a second assembly 800 comprised of a plurality of shielding covers 830. Here, the second assembly 800 may mean a structure in which a plurality of shielding covers 830 are integrated along a specific arrangement pattern.

According to some implementations, the second assembly 800 may be composed of a plurality of shielding covers 830 arranged in a honeycomb shape. In some implementations, a plurality of columns 810 may be mounted respectively within shielding covers 830. In FIG. 8, each of the plurality of columns 810 is depicted as having a circular shape on a plane, but this is not limited to this and may be changed in various ways.

The honeycomb-shaped arrangement of the second assembly 800 provides a geometrically optimized structure capable of arranging the maximum number of columns within the same area, and may have the effect of minimizing cross talk between columns 810 and improving beam quality.

Additionally, the centers 820 of the shielding covers 830 may be arranged at regular intervals along a second direction 801. In other words, the shielding covers 830 may be arranged at regular intervals along the second direction 801. Since the plurality of columns 810 are each mounted within the shielding covers 830, a uniform beam spacing may be maintained during the scanning and irradiation process of the electron beam when the charged particle beam device 100 operates.

In some implementations, the second direction 801 may form an acute angle with the x-direction. Additionally, the second direction 801 may form an acute angle with the y direction. Here, the x direction may be the movement direction of a stage (e.g., stage 123 in FIG. 1) supporting a sample (e.g., sample 121 in FIG. 1). The y direction may be the direction in which the electron beam is scanned along the surface of the sample 121.

According to some implementations, the columns 810 are not simply arranged in series along the x-direction or the y-direction but are arranged along a second direction 801 that forms an acute angle with the x-direction and the y-direction, thereby forming an optimized arrangement structure.

Specifically, the second assembly 800 according to the present disclosure has a honeycomb structure and an aligned arrangement in the second direction 801, thereby allowing as many columns 810 as possible to be arranged within the same area while securing the maximum spacing between beams scanned by individual columns.

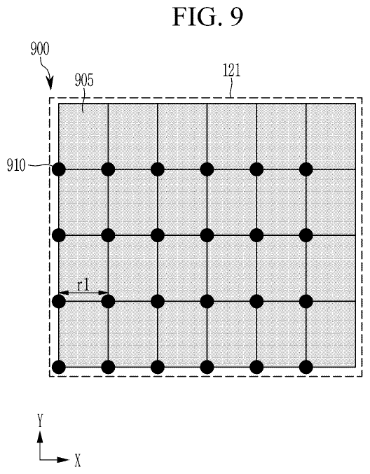

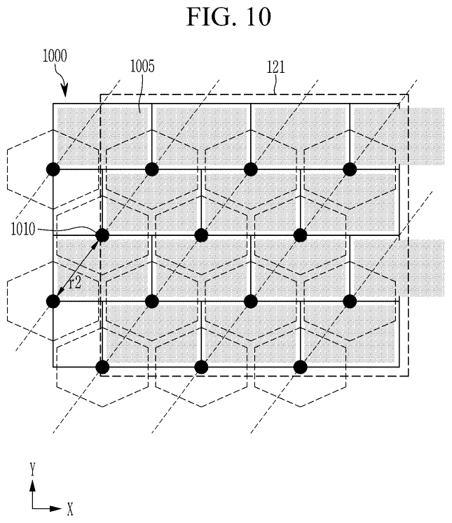

FIG. 9 is a drawing for explaining scanning the inspection area of a sample in a conventional charged particle beam device. FIG. 10 is a diagram illustrating scanning of an inspection area of a sample in a charged particle beam device according to some implementations. In FIGS. 9 and 10, the x direction is the movement direction of the stage, and the y direction is the scan direction.

Additionally, the sample 121 in FIGS. 9 and 10 may comprise a substrate used in various semiconductor processes, such as a photo mask, a reticle, and a wafer. It may be understood that the sample 121 illustrated in FIG. 9 and the sample 121 illustrated in FIG. 10 have the same area.

Referring to FIG. 9, the columns of a conventional charged particle beam device may not have a hexagonal prism shape. That is, the shape of each column may be a cylinder, a square column, or other modified structure.

Accordingly, a conventional charged particle beam device uses a first column array 900 in which a plurality of columns are arranged in a collinear array. Specifically, a conventional charged particle beam device examines a sample 121 by irradiating a first electron beam 910 using a first column array 900 and scanning a first inspection area 905.

For example, as illustrated in FIG. 9, the first column array 900 may be configured in a 4×6 array to examine a sample 121 in a conventional charged particle beam device. In other words, 24 columns are arranged to inspect the first inspection area 905 in a conventional charged particle beam device. However, this is only an example, and the first column array 900 may be configured as an m×n array (m and n are natural numbers) and may be changed in various ways depending on the area of the sample 121.

Referring to FIG. 10, the columns of the charged particle beam device according to the present disclosure (e.g., the charged particle beam device 100 of FIG. 1) may have a hexagonal columnar shape. That is, the columns of the charged particle beam device 100 may each have a hexagonal shape on a plane.

Accordingly, the charged particle beam device 100 uses a second column array 1000 in which a plurality of columns are arranged in a honeycomb structure. Specifically, the charged particle beam device 100 inspects the sample 121 by irradiating the second electron beam 1010 using the second column array 1000 and scanning the second inspection area 1005.

For example, as illustrated in FIG. 10, 14 columns are arranged to examine a sample 121 in a charged particle beam device 100. However, this is only an example, and the number of columns included in the second column array 1000 may vary depending on the area of the sample 121.

Referring to FIGS. 9 and 10 together, since the columns of the charged particle beam device 100 according to the present disclosure have a hexagonal prism shape, the number of columns required to examine a sample 121 may be reduced because hexagons having the same area as squares have centers of their nearest neighbor spaced further apart than centers of nearest neighbors of squares. For example, the first column array 900 may comprise 24 columns, while the second column array 1000 may comprise 14 columns. As the number of columns is reduced, the volume and power consumption of the charged particle beam device 100 may be reduced.

Referring to FIGS. 9 and 10 together, since the second column array 1000 of the charged particle beam device 100 according to the present disclosure has a honeycomb arrangement, the spacing between electron beams may be increased. In the present disclosure, a large spacing between electron beams may mean a wide spacing between columns. For example, a first spacing r1 between the first electron beams 910 and a second spacing r2 between the second electron beams 1010 may be greater than the first spacing r1. As the spacing between electron beams increases, electron beam interference phenomenon may be reduced, which may improve inspection accuracy.

Referring to FIGS. 9 and 10 together, as the spacing between the columns of the charged particle beam device 100 according to the present disclosure increases, the heat generated in each column may be evenly distributed. Accordingly, compared to conventional charged particle beam devices, the heat generation problem may be effectively controlled, enabling stable inspection for a long period of time.

As described above, the charged particle beam device 100 according to the present disclosure may implement a stable structure by securing a gap between beams by applying a honeycomb-shaped inclined array instead of the existing orthogonal array to the column array. This allows for increased integration of the column array while minimizing cross-talk between beams.

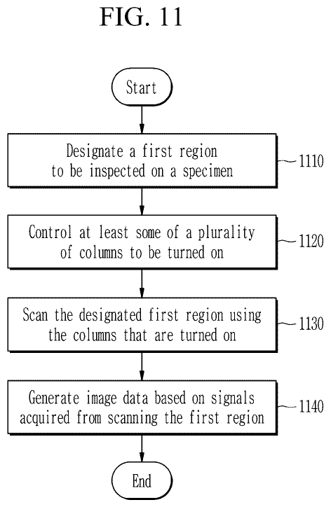

FIG. 11 is a flowchart illustrating an operation method of a charged particle beam device according to some implementations.

The operations described below may be performed by the charged particle beam device 100 of FIG. 1.

The operations in FIG. 11 may be performed sequentially, but are not necessarily performed sequentially. For example, the order of the actions may be changed, and at least two actions may be performed in parallel. In some implementations, some of the operations illustrated in FIG. 11 may be omitted, some operations may be combined, the order of some operations may be changed, or other operations may be added. Here, any content that overlaps with what has been previously stated may be simplified or omitted.

Referring to FIG. 11, in operation 1110, a charged particle beam device (e.g., the charged particle beam device 100 of FIG. 1) according to some implementations may designate a first region in a sample (e.g., the sample 121 of FIG. 1) where an inspection is to be performed.

According to some implementations, the charged particle beam device 100 may place and align a sample 121 on a stage (e.g., stage 123 of FIG. 1). The sample 121 may be placed and aligned on the stage 123 by, for example, a sample transfer module.

Thereafter, the charged particle beam device 100 may select the first region as a region of interest ROI by specifying the first region according to user settings or by utilizing an automatic analysis algorithm. For example, the charged particle beam device 100 may optimize the first region based on resolution, signal contrast, interaction characteristics with the electron beam, etc.

According to some implementations, the charged particle beam device 100 may map the location of the first region relative to a coordinate system within the device. The charged particle beam device 100 may detect slight deformations or deviations of the sample 121 during the scanning process and automatically perform a position correction.

In operation 1120, the charged particle beam device 100 according to some implementations may control power of at least some of the plurality of columns (e.g., column 110 of FIG. 1) to turn them on.

According to some implementations, the charged particle beam device 100 may activate the electron beam by switching on power to at least some of the plurality of columns 110. For example, the charged particle beam device 100 may automatically select a column 110 optimized for inspection. Additionally, for example, the charged particle beam device 100 may select a specific column based on user input. In some implementations, the charged particle beam device 100 may be activated by supplying power to selected columns.

In some implementations, the charged particle beam device 100 may control power to all of the columns 110 to be turned on. The charged particle beam device 100 according to the present implementations may simultaneously inspect a sample 121 using the plurality of columns 110, thereby expanding the scan range or improving the inspection speed.

According to some implementations, the charged particle beam device 100 may control power to some of the columns 110. For example, the charged particle beam device 100 may control the power of only some of the columns 110 to be turned on depending on specific inspection conditions or analysis purposes.

For example, if the charged particle beam device 100 determines that an inspection or re-inspection is required for a second region corresponding to a specific region among the first regions, it may activate only the column 110 corresponding to the second region. Additionally, for example, the charged particle beam device 100 may activate only the necessary columns 110 to minimize power consumption and heat generation. In this way, the number of columns 110 activated by the charged particle beam device 100 may be varied as needed.

In operation 1130, the first region may be scanned using the columns 110 controlled to ON.

In some implementations, the charged particle beam device 100 may scan a designated first region using an activated column 110. According to some implementations, the charged particle beam device 100 may determine a scan pattern to move the electron beam within the first region.

A charged particle beam device 100 according to some implementations may precisely aim an electron beam and move the beam at a uniform speed along a designated first area by utilizing an electron lens (e.g., condenser lens 113 or objective lens 117) and a deflection coil. In addition, the charged particle beam device 100 according to some implementations may maintain optimal scan conditions so as to effectively detect signals such as secondary electrons and backscattered electrons generated when an electron beam interacts with a sample 121.

According to some implementations, the charged particle beam device 100 may adjust the scan path in real time or dynamically adjust the scan speed based on, for example, surface characteristics detected during inspection. Through this, the charged particle beam device 100 may precisely scan the first region to maximize inspection efficiency and secure optimal image quality.

In operation 1140, image data may be generated based on a signal obtained by scanning the first region.

According to some implementations, the charged particle beam device 100 may acquire a signal emitted from a sample 121. Specifically, the charged particle beam device 100 may detect various signals generated when an electron beam interacts with the surface of a sample 121. For example, the charged particle beam device 100 may detect signals such as secondary electrons, backscattered electrons, and X-rays.

According to some implementations, the charged particle beam device 100 may generate image data based on the acquired signal. For example, the charged particle beam device 100 may convert a detected signal into digital image data and apply a noise removal filter to improve the signal-to-noise ratio SNR. Additionally, for example, the charged particle beam device 100 may perform post-processing processes such as contrast adjustment, resolution enhancement, and pattern analysis on the acquired image data.

According to some implementations, the charged particle beam device 100 may store the generated image data in a memory (e.g., memory 160 of FIG. 2). However, it is not limited thereto, and the charged particle beam device 100 may also store image data in an external storage device.

According to some implementations, the charged particle beam device 100 may output the generated image data through a display (e.g., the display 180 of FIGS. 1 and 2).

According to some implementations, the charged particle beam device 100 may output image data corresponding to each scanned area through a display 180 using a plurality of columns (e.g., columns 110).

For example, the charged particle beam device 100 may simultaneously output image data scanned individually by columns 110 through a display 180. Additionally, for example, the charged particle beam device 100 may configure the plurality of screens on the display 180 to individually display data scanned by each column 110, or may integrate images acquired from the plurality of columns 110 into a single composite image and output them. Additionally, the charged particle beam device 100 may selectively enlarge and output only the image data of a specific column 110 according to the user's settings.

As described above, the charged particle beam device 100 may effectively display image data acquired from the plurality of columns 110 through the display 180, thereby enabling more accurate and intuitive analysis.

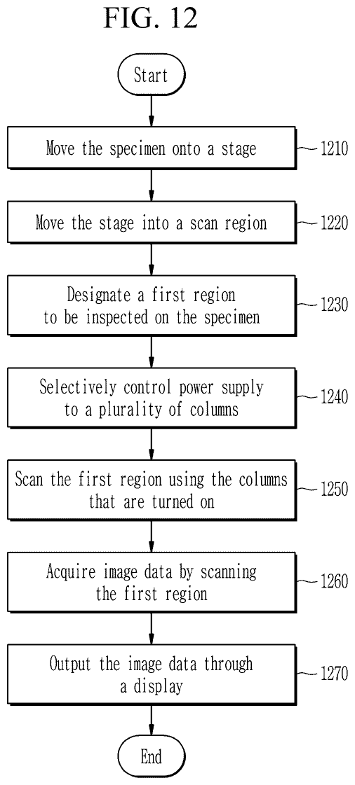

FIG. 12 is a flowchart illustrating an operation method of a charged particle beam device according to some implementations.

The operations described below may be performed by the charged particle beam device 100 of FIG. 1.

The operations in FIG. 12 may be performed sequentially, but are not necessarily performed sequentially. For example, the order of the actions may be changed, and at least two actions may be performed in parallel. In some implementations, some of the operations illustrated in FIG. 12 may be omitted, some operations may be combined, the order of some operations may be changed, or other operations may be added. Here, any content that overlaps with what has been previously stated may be simplified or omitted.

Referring to FIG. 12, in operation 1210, a charged particle beam device (e.g., the charged particle beam device 100 of FIG. 1) according to some implementations may move a specimen (e.g., the sample 121 of FIG. 1) onto a stage (e.g., the stage 123 of FIG. 1).

In some implementations, the charged particle beam device 100 may move a sample 121 over a stage 123. The charged particle beam device 100 may move a sample onto the stage 123 using a sample transfer module. The charged particle beam device 100 may perform position adjustment and alignment functions so that the sample 121 is accurately placed in a predetermined direction and angle.

At operation 1220, the charged particle beam device 100 may move the stage into a scan region, e.g., the inspection area.

In some implementations, the charged particle beam device 100 may move the stage 123 into the inspection area so that the sample 121 is placed in a position suitable for inspection. According to some implementations, the charged particle beam device 100 may move a sample 121 to an inspection area by utilizing a stage driving device (e.g., the stage driving device 125 of FIG. 1).

According to some implementations, the charged particle beam device 100 may monitor the movement status of the stage 123 in real time, detect errors, and automatically adjust the position.

In operation 1230, the charged particle beam device 100 may designate a first region in the sample 121 where an inspection is to be performed.

According to some implementations, the charged particle beam device 100 may designate a specific area in the sample 121 where an inspection is to be performed as a first region. For example, the first region may be set directly by the user, or may be selected as a region of interest ROI through an automatic analysis algorithm of the charged particle beam device 100.

According to some implementations, the charged particle beam device 100 may designate the first region based on resolution, signal contrast, interaction characteristics with the electron beam, etc. According to some implementations, the charged particle beam device 100 may designate a region where there is a high need to analyze the surface characteristics of the sample 121 and inspect it as a first region.

In operation 1240, the charged particle beam device 100 may selectively control power to the plurality of columns.

In some implementations, the charged particle beam device 100 may selectively control power to some or all of the plurality of columns 110. For example, the charged particle beam device 100 may activate only the necessary columns 110 depending on the inspection purpose, or may activate all columns 110 simultaneously.

In some implementations, the charged particle beam device 100 may select certain columns 110 to optimize a particular resolution or signal contrast. In some implementations, the charged particle beam device 100 may keep some columns 110 powered off to reduce power consumption. As described above, the charged particle beam device 100 may dynamically adjust the power of the column according to the inspection environment to provide optimal inspection conditions.

At operation 1250, the charged particle beam device 100 may scan the first region using the column 110 which has been turned on.

In some implementations, the charged particle beam device 100 may scan a first region using a column 110 that is controlled to be turned on. According to some implementations, the charged particle beam device 100 may scan a designated first area at a uniform speed using an electron beam.

According to some implementations, the charged particle beam device 100 may adjust the scan path in real time or automatically adjust the scan speed according to changes in the characteristics of the sample 121.

In operation 1260, the charged particle beam device 100 may acquire image data by scanning the first region.

According to some implementations, the charged particle beam device 100 may scan a first region to obtain image data. According to some implementations, the charged particle beam device 100 may detect a signal emitted from a sample 121 and convert it into image data.

For example, the charged particle beam device 100 may apply a noise removal filter to improve the signal-to-noise ratio SNR, and may also perform image contrast adjustment and resolution optimization. According to some implementations, the charged particle beam device 100 may analyze acquired data in real time.

In operation 1270, the charged particle beam device 100 may output image data through a display (e.g., display 180 of FIG. 1).

According to some implementations, the charged particle beam device 100 may output generated image data through a display 180. For example, the charged particle beam device 100 may display scanned image data in real time on a display 180 to support analysis by the user.

For example, the charged particle beam device 100 may output image data scanned individually by columns 110 simultaneously (or together) through a display 180. Additionally, for example, the charged particle beam device 100 may configure a plurality of screens on the display 180 to individually display data scanned by each column 110, or may integrate images acquired from the plurality of columns 110 into a single composite image and output them. Additionally, the charged particle beam device 100 may selectively enlarge and output only the image data of a specific column 110 according to the user's settings.

According to some implementations, the charged particle beam device 100 may provide inspection results more intuitively by applying image zoom in/out functions, color emphasis processing, data overlay, etc. In some implementations, the charged particle beam device 100 may perform additional analysis based on data output to the display 180 or may re-examine specific areas based on user input.

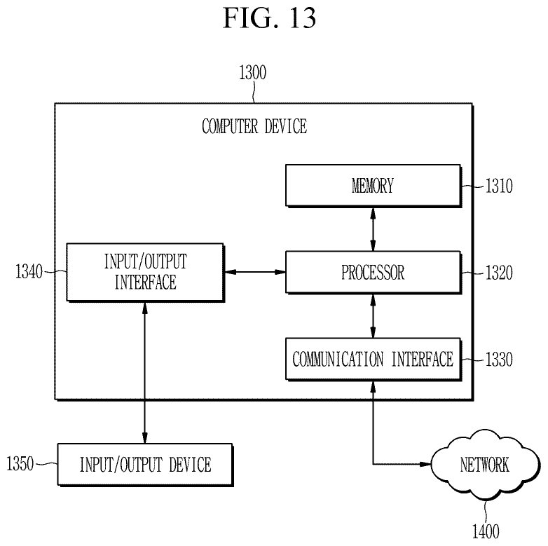

FIG. 13 is a diagram illustrating an example of a computer device implementing a charged particle beam device according to some implementations. The charged particle beam device 100 of FIG. 1 may be implemented by the computer device 1300 illustrated in FIG. 13.

Referring to FIG. 13, a computer device 1300 may comprise a memory 1310, a processor 1320, a communication interface 1330, and an input/output interface 1340.

Memory 1310 is a computer-readable storage medium and may comprise random access memory RAM, read only memory ROM, and a permanent mass storage device such as a disk drive. Additionally, an operating system and at least one program code may be stored in the memory 1310. These software components may be loaded into the memory 1310 from a computer-readable recording medium separate from the memory 1310. Such separate computer-readable recording media may comprise computer-readable recording media such as a hard disk, flash memory, an optical disk, an external hard disk, etc. Additionally, these software components may be loaded into memory 1310 via a communication interface 1330.

The processor 1320 may be configured to process instructions of a computer program by performing basic arithmetic, logic, and input/output operations. The commands may be provided to the processor 1320 by memory 1310 or a communication interface 1330.

The communication interface 1330 may provide a function for the computer device 1300 to communicate with other devices via a network 1400. The communication method is not limited, and may comprise not only a communication method utilizing a communication network (e.g., a mobile communication network, wired Internet, wireless Internet, or broadcasting network) that the network 1400 may comprise, but also short-range wireless communication between devices. For example, the network 1400 may comprise any one or more of networks such as a personal area network PAN, a local area network LAN, a campus area network CAN, a metropolitan area network MAN, a wide area network WAN, a broadband network BBN, and the Internet. Additionally, the network 1400 may comprise any one or more of network topologies including, but not limited to, a bus network, a star network, a ring network, a mesh network, a star-bus network, a tree, or a hierarchical network.

The input/output interface 1340 may serve as an interface that may transmit commands or data input from a user or an input/output device 1350 to other component(s) of the computer device 1300. Additionally, the input/output interface 1340 may output commands or data received from other components of the computer device 1300 to a user or an input/output device 1350. For example, the input/output device 1350 may comprise an input device such as a microphone, a keyboard, or a mouse, and the output device may comprise an output device such as a display or a speaker.

In certain aspects, the subject matter of the present application is directed to methods of operating a charged particle beam device that include designating a first region of a sample to be inspected, controlling power supply to turn on at least some of a plurality of columns, scanning the first region using the columns whose power is turned on, and generating image data based on signals obtained by scanning the first region.

The methods of operating the charged particle beam device may further include outputting the image data of the first region through a display.

The methods may further include outputting the respective image data obtained by scanning using the respective columns whose power is turned on.

The methods may further include turning on the power of all of the plurality of columns.

The methods may further include designating a second region as a partial region of the first region and turning on the power of columns corresponding to the second region among the plurality of columns.

In the methods of operating the charged particle beam device, the charged particle beam device may comprise a plurality of columns each having a polygonal shape in a plan view.

The plurality of columns may be arranged in a honeycomb pattern in a plan view.

The charged particle beam device may further include a plurality of shielding covers respectively surrounding the plurality of columns.

The plurality of shielding covers may comprise a material having a shielding effect, such as a permalloy.

The plurality of shielding covers may have a hexagonal shape in a plan view.

The plurality of shielding covers may be arranged in a honeycomb pattern in a plan view.

The implementations described above may be implemented in the form of a computer program that may be executed through various components on a computer, and such a program may be recorded on a computer-readable medium. At this time, the medium may comprise magnetic media such as hard disks, floppy disks, and magnetic tapes, optical recording media such as CD-ROMs and DVDs, magneto-optical media such as floptical disks, and hardware devices specifically configured to store and execute program instructions, such as ROMs, RAMs, flash memories, etc.

Unless the order of steps constituting a method according to some implementations is explicitly stated or contradicted, the steps may be performed in any suitable order. The present disclosure is not necessarily limited to the order in which the above steps are described.

Any use of examples or exemplary language in this specification is intended merely to illustrate the invention in more detail and is not intended to limit the scope of the invention. Additionally, one of ordinary skill in the art will recognize that various modifications, combinations, and changes may be made within the scope of the patent claims or their equivalents.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While this disclosure has been described in connection with what is presently considered to be practical implementations, it should be understood that the disclosure is not limited to the disclosed implementations, but, on the contrary, is intended to cover various modifications and equivalent arrangements included within the spirit and scope of the appended claims.

What is claimed is:

1. A charged particle beam device comprising:
a plurality of columns, wherein each column of the plurality of columns is configured to scan an electron beam on a sample;
a plurality of shielding covers respectively surrounding each column of the plurality of columns;
a chamber coupled to the plurality of columns, the chamber comprising a stage configured to support the sample, wherein the stage is apart from ends of the plurality of columns; and
a detector configured to detect electrons emitted from the sample,
wherein each column of the plurality of columns has a polygonal shape in a plan view.

2. The charged particle beam device of claim 1, wherein each column of the plurality of columns has a hexagonal shape in a plan view.

3. The charged particle beam device of claim 2, wherein the hexagonal shape comprises
a pair of first sides facing each other and
second sides and third sides connecting the pair of first sides,
wherein the second sides and the third sides are symmetric about an imaginary line passing through a center of the column and parallel to the first sides,
wherein a length of the second sides is different from a length of the first sides, and
wherein the length of the second sides is equal to a length of the third sides.

4. The charged particle beam device of claim 1, wherein centers of each column of the plurality of columns are spaced apart from each other at regular intervals along a first direction, and the first direction forms an acute angle with a moving direction of the stage.

5. The charged particle beam device of claim 4, wherein the plurality of columns are arranged in a honeycomb pattern in a plan view.

6. The charged particle beam device of claim 1, comprising a controller communicatively connected to the detector,
wherein the controller is configured to generate image data related to defects of the sample based on data obtained from the detector.

7. The charged particle beam device of claim 6, comprising a display,
wherein the controller is configured to output the image data through the display.

8. A charged particle beam device comprising:
a plurality of shielding covers having polygonal shapes in a plan view;
a plurality of columns, wherein each column of the plurality of columns is mounted in a respective shielding cover of the plurality of shielding covers and wherein each column of the plurality of columns is configured to scan an electron beam on a sample;
a chamber coupled to the plurality of columns, wherein the chamber includes a stage that is configured to support the sample and wherein the stage is apart from ends of the plurality of columns; and
a detector configured to detect electrons emitted from the sample.

9. The charged particle beam device of claim 8, wherein each shielding cover of the plurality of shielding covers has a hexagonal shape in a plan view.

10. The charged particle beam device of claim 9, wherein the hexagonal shape comprises
a pair of first sides facing each other and
second sides and third sides connecting the first sides,
wherein the second sides and the third sides are symmetric about an imaginary line passing through a center of the shielding cover and parallel to the first sides,
wherein a length of the second sides is different from a length of the first sides, and
wherein the length of the second sides is equal to a length of the third sides.

11. The charged particle beam device of claim 8, wherein centers of each shielding cover of the plurality of shielding covers are spaced apart from each other at regular intervals along a first direction, and the first direction forms an acute angle with a moving direction of the stage.

12. The charged particle beam device of claim 11, wherein the shielding covers are arranged in a honeycomb pattern in a plan view.

13. The charged particle beam device of claim 8, comprising a controller communicatively connected to the detector,
wherein the controller is configured to generate image data related to defects of the sample based on data obtained from the detector.

14. The charged particle beam device of claim 13, comprising a display, wherein the controller is configured to output the image data through the display.

15. A charged particle beam device comprising:
a plurality of columns, wherein each column of the plurality of columns has a polygonal shape in a plan view and wherein each column of the plurality of columns is configured to scan an electron beam on a sample;
a memory; and
a processor,
wherein the memory stores instructions which, when executed by the processor, cause the charged particle beam device to:
designate a first region of the sample to be inspected;
turn on power for at least some of the plurality of columns;
scan the first region using the columns of the plurality of columns which have power turned on; and
generate image data based on signals obtained from the scanned first region.

16. The charged particle beam device of claim 15, comprising a display,
wherein the instructions, when executed by the processor, cause the charged particle beam device to output the image data obtained by scanning the first region through the display.

17. The charged particle beam device of claim 16, wherein the instructions, when executed by the processor, cause the charged particle beam device to output image data corresponding to each column of the plurality of columns which have power turned on.

18. The charged particle beam device of claim 15, wherein the instructions, when executed by the processor, cause the charged particle beam device to turn on power to all of the plurality of columns.

19. The charged particle beam device of claim 15, wherein the instructions, when executed by the processor, cause the charged particle beam device to designate a partial region of the first region as a second region; and
turn on power to columns of the plurality of columns corresponding to the second region.

20. The charged particle beam device of claim 15, comprising a plurality of shielding covers, each shielding cover of the plurality of shielding covers surrounding a respective column of the plurality of columns, wherein the plurality of shielding covers comprises permalloy.
